(19) United States
(12) Patent Application Publication
(10) Pub. No.: US 2022/0215144 A1
(43) Pub. Date: Jul. 7, 2022

(54) Learning Apparatus, Learning Method and Learning Program

(71) Applicant: Nippon Telegraph and Telephone Corporation, Tokyo (JP)

(72) Inventors: Masahiro Sotoma, Musashino-shi, Tokyo (JP); Masayuki Tsuda, Musashino-shi, Tokyo (JP)

(21) Appl. No.: 17/606,873

(22) PCT Filed: May 16, 2019
(86) PCT No.: PCT/JP2019/019547

§ 371 Date: Oct. 27, 2021

(51) Int. Cl. G06F 30/27

(52) U.S. Cl. CPC G06F 30/27

(57) ABSTRACT

A learning device includes: a storage device configured to store input data that contains a plurality of data sets relating to a first event and a plurality of data sets relating to a second event, the number of the data sets relating to the second event being smaller than the number of the data sets relating to the first event; a copula function estimation unit configured to estimate a copula function and a parameter for use in the copula function, based on the data sets relating to the second event; a simulation unit configured to generate a data set relating to the second event through simulation using the copula function and the parameter; and a learning unit configured to learn an estimation model for distinguishing the first event and the second event from each other, with reference to the input data, and the data set relating to the second event generated by the simulation unit.

### TECHNICAL FIELD

The present invention relates to a learning device, a learning method, and a learning program that perform machine learning with reference to a plurality of data sets.

### BACKGROUND ART

Typically, in maintenance and inspection of various types of equipment such as machines and devices, it is estimated whether or not the various types of equipment have a failure based on a value of a sensor installed on each of the corresponding equipment. Failures estimated based on sensor values may include a defect such as degradation of the corresponding equipment. Failure estimation of various types of equipment is advantageous for promoting the efficiency of maintenance and inspection and maintaining the performance, service quality, or the like.

Recently, it is sometimes the case where determination of whether or not various types of equipment has a failure is made by machine learning using data obtained from sensors and various types of data indicating the circumference situation. In the machine learning, a model for detecting a failure of each type of equipment is generated. In the machine learning, failure data indicating that there is a failure, and non-failure data indicating that there is no failure are referenced as teaching data.

However, typically, the number of pieces of non-failure data tends to be larger than the number of pieces of failure data. Of teaching data, data with the larger number of data sets indicating either of the events is referred to as “major data”, and data with the smaller number of data sets is referred to as “minor data”. Also, teaching data constituted by major data and minor data is referred to as “imbalanced data”.

Machine learning constructs a model for minimizing the wrong answer rate. However, if teaching data has a high degree of imbalance in the number of data sets between major data and minor data, the model obtained by the machine learning may tend to give a correct answer regarding the state or phenomenon of the major data. That is to say, the model obtained by the machine learning tends to minimize the wrong answer rate of the major data. Therefore, a model obtained using teaching data that has a larger number of non-failure data sets than the number of failure data sets may result in a reduction in the correct answer rate regarding failure, which must essentially be of interest.

As a method that deals with a bias of machine learning results using imbalanced data, two broadly classified approaches are known. One of the approaches is a method in which in a process for constructing a machine learning model, adjustment or the like of various types of parameters included in a learning method is performed. In this method, a learner has innovated functions of comparing an actual result with an estimation result and feeding back adjustment of a parameter or a result thereof to the estimation model, and thereby the method achieves an improved estimation accuracy. In this case, because the number of data sets of minor data is not changed and thus the feature amount that the learner can directly obtain from the minor data does not change, there is in principle an influence of the representativeness of the data for the population.

The other approach is a resampling method. In the resampling method, the number of minor data is increased by some means, or the number of major data is decreased by some means, so that the data are balanced. Typically, the former is referred to as “upsampling”, and the latter is referred to as “downsampling” (NPL 1). In machine learning, there are also cases where both upsampling and downsampling are used at the same time.

Also, a copula is a mathematical method that can express mutual dependency between variates and can change the intensity or aspect of the mutual dependency using functional parameters. The mutual dependency means not only a linear relationship of an entire distribution according to normal distribution as indicated by Pearson's correlation coefficient, but also a relationship that includes variety of distribution profiles and a difference in relationship due to positions of distribution.

Also, in the UCI Machine Learning Repository, observational data of neutron stars is released to the public (NPLs 2 and 3).

### CITATION LIST

### Non Patent Literature

[NPL 1] Foster Provost, Machine Learning from Imbalanced Data Sets 101, AAAI Technical Report WS-00-05, 2000
[NPL 2] R. J. Lyon, “HTRU2” data, UCI Machine Learning Repository, DOI: 10.6084/m9.figshare.3080389.v1., https://archive.ics.uci.ed u/ml/datasets/HTRU2
[NPL 3] R. J. Lyon, B. W. Stappers, S. Cooper, J. M. Brooke, J. D. Knowles, Fifty Years of Pulsar Candidate Selection: From simple filters to a new principled real-time classification approach, Monthly Notices of the Royal Astronomical Society 459 (1), 1104-1123, DOI: 10.1093/mnras/stw656

### SUMMARY OF THE INVENTION

### Technical Problem

In many cases, data referenced in machine learning is multidimensional data, and a resampling method is required that can reflect various distributions of data and various relationships between many variates, and thus a resampling method using a copula is considered to be usable. However, the resampling method disclosed in NPL 1 does not employ a copula.

Therefore, an object of the present invention is to provide a learning device, a learning method, and a learning program that perform resampling using a copula.

### Means for Solving the Problem

In order to solve the aforementioned problem, a first aspect of the present invention relates to a learning device for performing machine learning with reference to a plurality of data sets. The learning device according to the first aspect of the present invention includes: a storage device configured to store input data that contains a plurality of data sets relating to a first event, and a plurality of data sets relating to a second event, the number of the data sets relating to the second event being smaller than the number of the data sets relating to the first event; a copula function estimation unit configured to estimate a copula function and a parameter for use in the copula function, based on the data sets relating to the second event; a simulation unit configured to generate a data set relating to the second event through simulation using the copula function and the parameter; and a learning unit configured to learn an estimation model for distinguishing the first event and the second event from each other, with reference to the input data, and the data set relating to the second event generated by the simulation unit.

The learning device may further include a parameter generation unit configured to generate a new parameter other than the parameter estimated by the copula function estimation unit, and the simulation unit may generate a data set relating to the second event for the new parameter through simulation using the copula function and the new parameter, and the learning unit may learn an estimation model for the new parameter, with reference to the input data, and the data set relating to the second event generated for the new parameter by the simulation unit.

The learning device may further include a verification unit configured to input validation data that contains a plurality of data sets relating to the first event and a plurality of data sets relating to the second event to the estimation model learned by the learning unit, compare an event indicated by the validation data with an event obtained from the estimation model, and output the uncertainty of the estimation model.

A second aspect of the present invention relates to a learning method for performing machine learning with reference to a plurality of data sets. The learning method according to the second aspect of the present invention includes: a step of a computer storing, in a storage device, input data that contains a plurality of data sets relating to a first event, and a plurality of data sets relating to a second event, the number of the data sets relating to the second event being smaller than the number of the data sets relating to the first event; a step of the computer estimating a copula function and a parameter for use in the copula function, based on the data sets relating to the second event; a step of the computer generating a data set relating to the second event through simulation using the copula function and the parameter; and a step of the computer learning an estimation model for distinguishing the first event and the second event from each other, with reference to the input data and the generated data set relating to the second event.

The learning method may further include: a step of the computer generating a new parameter other than the parameter estimated in the step of estimating; a step of the computer generating a data set relating to the second event for the new parameter through simulation using the copula function and the new parameter; and a step of the computer learning an estimation model for the new parameter, with reference to the input data, and the data set relating to the second event generated for the new parameter.

The learning method may further include a step of the computer inputting validation data that contains a plurality of data sets relating to the first event and a plurality of data sets relating to the second event to the estimation model, comparing an event indicated by the validation data with an event obtained from the estimation model, and outputting the uncertainty of the estimation model.

A third aspect of present invention relates to a learning program for causing a computer to function as the learning device according to the first aspect of the present invention.

### Effects of the Invention

According to the present invention, it is possible to provide a learning device, a learning method, and a learning program that perform resampling using a copula.

### BRIEF DESCRIPTION OF DRAWINGS

FIG. 1 is a diagram illustrating a hardware configuration and functional blocks of a learning device according to an embodiment of the present invention.

FIG. 2 is a diagram illustrating input data.

FIG. 3 is a flowchart illustrating copula function estimation processing executed by a copula function estimation unit.

FIG. 4 is a flowchart illustrating parameter generation processing executed by a parameter generation unit.

FIG. 5 is a diagram illustrating simulation data made by a simulation unit.

FIG. 6 is a flowchart illustrating simulation processing executed by the simulation unit.

FIG. 7 is a flowchart illustrating learning processing executed by a learning unit.

FIG. 8 is a flowchart illustrating verification processing executed by a verification unit.

FIG. 9 is a diagram illustrating input data and validation data that are used in a working example.

FIG. 10 illustrate examples of a plurality of data sets generated by the simulation unit in the working example.

FIG. 11 illustrate examples of a plurality of data sets that are input to an estimation model in the working example.

FIG. 12 illustrates an example of a verification result in the working example.

### DESCRIPTION OF EMBODIMENTS

Hereinafter, an embodiment of the present invention will be described with reference to the drawings. In the following description of the drawings, the same or like reference numerals are given to the same or like parts.

### (Learning Device)

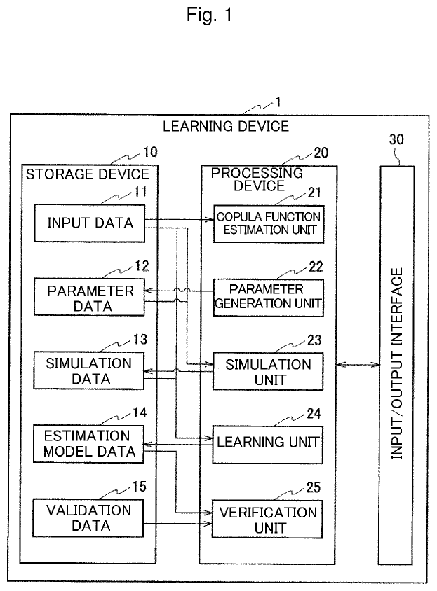

A learning device 1 according to an embodiment of the present invention will be described with reference to FIG. 1. The learning device 1 performs machine learning with reference to a plurality of data sets, and generates a model. Furthermore, the learning device 1 verifies the generated model.

The learning device 1 includes a storage device 10, a processing device 20, and an input/output interface 30. The learning device 1 may be one computer that includes the storage device 10, the processing device 20, and the input/output interface 30, or may be a virtual computer constituted by a plurality of pieces of hardware. As a result of such a computer executing a learning program, the functions shown in FIG. 1 are realized.

The storage device 10 is a ROM (Read Only Memory), a RAM (Random access memory), a hard disc, or the like, and stores various types of data such as input data, output data, and intermediate data for use in processing executed by the processing device 20. The processing device 20 is a CPU (Central Processing Unit), and executes processing of the learning device 1 by reading and writing the data stored in the storage device 10, and inputting and outputting data to and from the input/output interface 30. The input/output interface 30 inputs, to the processing device 20, data input from an input device such as a mouse and a keyboard, and outputs, to an output device such as a printer and a display device, data output from the processing device 20. Also, the input/output interface 30 may be an interface via which communication with another computer is performed.

The storage device 10 stores input data 11, parameter data 12, simulation data 13, estimation model data 14, and validation data 15.

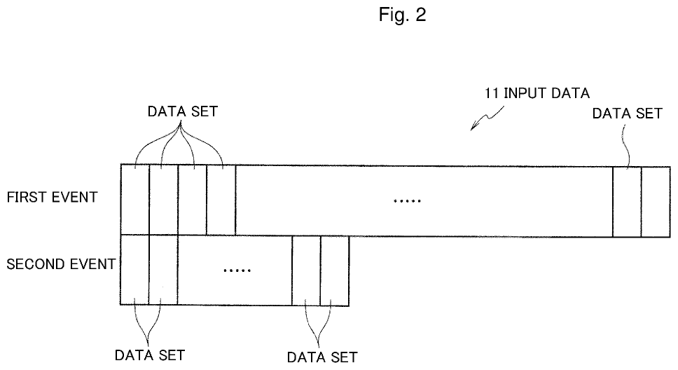

The input data 11 contains a plurality of data sets relating to a first event, and a plurality of data sets relating to a second event. As shown in FIG. 2, the input data 11 contains a plurality of data sets. Some data sets of the plurality of data sets relate to the first event, and the remaining data sets relate to the second event. Each of the data sets includes values of a plurality of items. In the embodiment of the present invention, each data set includes values of two variables, namely, a variable A and a variable B.

As shown in FIG. 2, the number of the data sets relating to the second event is smaller than the number of the data sets relating to the first event. The plurality of data sets relating to the first event are so-called major data, and the plurality of data sets relating to the second event are minor data.

In the embodiment of the present invention, the first event means, for example, that equipment does not have a failure, and the second event means that equipment has a failure. The data sets relating to the first event include two sensor values respectively obtained from two sensors of the equipment that does not have a failure. The data sets relating to the second event include two sensor values respectively obtained from two sensors of the equipment that has a failure. Note that each of the data sets may also include data indicating the circumference situation such as a temperature and a humidity when the values of the data set were acquired. Also, equipment such as a power pole installed outdoors may degrade due to corrosion or the like depending on the circumference environment, and there may be cases where it is difficult to install a sensor. Therefore, data sets of equipment that can have a failure due to the circumference environment may include data indicating the circumference situation such as a temperature and a humidity of the circumference of the place where the equipment is installed. Accordingly, values included in data sets need only be data relating to a failure of equipment, and sensor values and data indicating the circumference situation are merely examples.

The parameter data 12 includes a value of a parameter for a copula function generated by a later-described parameter generation unit 22. If there are a plurality of parameters for one copula function, the parameter data 12 holds values of the parameters in association with the copula function.

The simulation data 13 is a data set relating to the second event generated by a later-described simulation unit 23. The simulation data 13 may also include a plurality of data sets.

The estimation model data 14 is data for specifying a model obtained by a later-described learning unit 24. In the embodiment of the present invention, the estimation model data 14 is used to distinguish the first event and the second event from each other. The estimation model data 14 includes data for specifying an estimation model generated based on the parameter that corresponds to the input data 11. The estimation model data 14 may further include data for specifying an estimation model generated based on the parameter generated by the parameter generation unit 22.

The validation data 15 is data to be referenced for verifying the estimation model data 14. Similar to the input data 11, the validation data 15 includes a plurality of data sets relating to the first event, and a plurality of data sets relating to the second event. Also, similar to the input data 11, a data set included in the validation data 15 includes values that correspond to two variables, namely, the variable A and the variable B. Also, the ratio of the number of the data sets relating to the first event to the number of the data sets relating to the second event in the validation data 15 is the same as the ratio in the input data 11. The input data 11 and the validation data 15 may also be generated by, for example, dividing a plurality of data sets belonging to the same population into two.

The processing device 20 includes a copula function estimation unit 21, the parameter generation unit 22, the simulation unit 23, the learning unit 24, and a verification unit 25.

The copula function estimation unit 21 estimates a copula function and a parameter for use in the copula function, based on the data sets relating to the second event of the input data 11. The copula function indicates a structure in which the variable A and the variable Bare correlated. The parameter for use in the copula function indicates a phase of the correlated structure indicated by the copula function, and relates to the degree of variation in the values of the variables, and the like. If the copula function includes a plurality of parameters, the copula function estimation unit 21 estimates the parameters.

In the embodiment of the present invention, since each data set includes two variables, namely, the variable A and the variable B, the copula function estimation unit 21 estimates an optimal copula from the two variable copulas. If the data set includes three variables or more, the copula function estimation unit 21 may estimate a copula that corresponds to the plurality of variables, or may use a method such as a vine copula that describes a relationship among the whole variables using a combination of two variables.

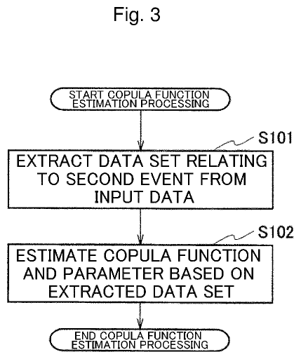

A copula function estimation processing that is executed by the copula function estimation unit 21 will be described with reference to FIG. 3.

In step S101, the copula function estimation unit 21 extracts, from the input data 11, the plurality of data sets relating to the second event. In step S102, the copula function estimation unit 21 estimates a copula function and a parameter for the copula function based on the data sets extracted in step S101. The copula function estimation processing is thus ended.

The parameter generation unit 22 generates a new parameter other than the parameter estimated by the copula function estimation unit 21. The parameter generation unit 22 stores the generated parameter in the parameter data 12. If the copula function estimated by the copula function estimation unit 21 includes a plurality of parameters, the parameter generation unit 22 stores, in the parameter data 12, a parameter set in which the generated parameters are associated with each other. The parameter generation unit 22 generates one or more parameters or parameter sets.

The parameter generation unit 22 may equally divide the range that the parameters can cover, and determine the values of the parameters. Alternatively, the parameter generation unit 22 may randomly generate values within the ranges that the parameters can cover, and determine the values of the parameters.

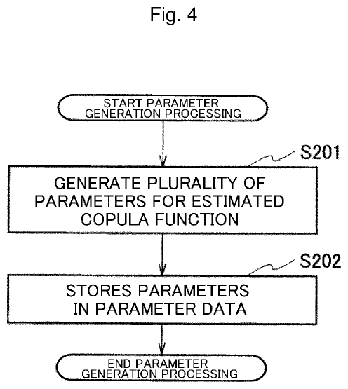

A parameter generation processing that is executed by the parameter generation unit 22 will be described with reference to FIG. 4.

In step S201, the parameter generation unit 22 generates a plurality of parameters for the function estimated by the copula function estimation unit 21. In step S202, the parameter generation unit 22 stores the plurality of parameters generated in step S201 in the parameter data 12. The parameter generation processing is thus ended.

The simulation unit 23 generates a data set relating to the second event, through simulation using the copula function and the parameter that were estimated by the copula function estimation unit 21. The data set generated by the simulation unit 23 is a data set that has a different data phase such as the intensity of the mutual dependency or a variation while maintaining the correlated structure between the variables in the data sets relating to the second event of the input data 11. The simulation unit 23 increases the number of data sets relating to the second event that are smaller in the number of data sets in the input data 11, so that the imbalance of the input data 11 is reduced.

The simulation unit 23 generates, through the simulation, the data set relating to the second event for which new values for the variable A and the variable B are set. Here, the variable A and the variable B of the data set newly generated by the simulation unit 23 may be the same as or different from the variable A and the variable B of the data sets relating to the second event of the input data 11.

The simulation unit 23 further generates a data set relating to the second event for the new parameter generated by the parameter generation unit 22, through simulation using the copula function and the new parameter. The simulation unit 23 uses the parameter or the parameter set generated by the parameter generation unit 22 to reference the copula function estimated by the copula function estimation unit 21. The simulation unit 23 generates, for each parameter or parameter set, a data set relating to the second event for which new values for the variable A and the variable B are set, through the simulation. The data sets relating to the second event generated by the simulation unit are stored in the simulation data 13 in association with the parameters.

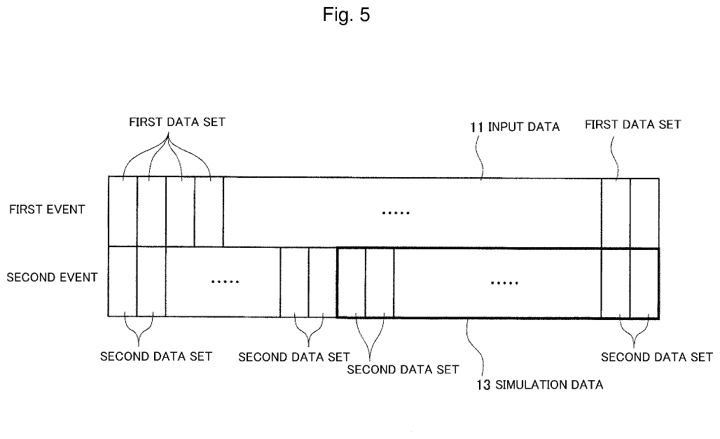

The simulation unit 23 preferably generates, through the simulation, data sets of the number obtained by subtracting the number of data set of the minor data from the number of data sets of the major data. With this, as shown in FIG. 5, the number of data sets indicating the first event and the number of data sets indicating the second event match each other. By the simulation unit 23 increasing a plurality of data sets that have different data phases such as the intensity of the mutual dependency or the variation while maintaining the correlated structure between the variables in the minor data, it is possible to eliminate a defect due to an imbalance in the number of data sets of the major data and the minor data.

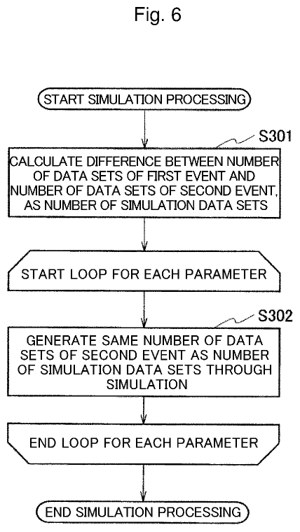

A simulation processing that is executed by the simulation unit 23 will be described with reference to FIG. 6.

In step S301, the simulation unit 23 calculates a difference between the number of data sets of the first event in the input data 11 and the number of data sets of the second event, as the number of simulation data sets.

The processing in step S302 is repeated for each parameter. The parameters include the parameter estimated by the copula function estimation unit 21. Also, the parameters may include parameters generated by the parameter generation unit 22.

In step S302, using the copula function estimated by the copula function estimation unit 21 and the processing target parameters, the same number of data sets as the number of simulation data sets calculated in step S301 are generated. Here, the data sets to be generated relates to the second event. After the completion of the processing in step S302 for the parameters, the simulation processing is ended.

The learning unit 24 learns an estimation model for distinguishing the first event and the second event from each other, with reference to the input data 11, and the data sets relating to the second event generated by the simulation unit 23. Here, the learning unit 24 learns an estimation model for the parameter estimated by the copula function estimation unit 21 based on the input data 11. Upon input of a data set, the estimation model outputs an event indicated by this data set. In the embodiment of the present invention, the estimation model determines, upon input of a data set that includes a variable A and a variable B, whether this data set relates to the first event or this data set relates to the second event.

The learning unit 24 further learns an estimation model for the parameter generated by the parameter generation unit 22. The learning unit 24 learns the estimation model for the new parameter, with reference to the input data 11, and the data sets relating to the second event generated for the new parameters by the simulation unit 23. If the parameter generation unit 22 generates a plurality of parameters, the learning unit 24 learns the estimation model for each parameter.

The learning unit 24 stores the estimation model learned for each parameter in the estimation model data 14. In the embodiment of the present invention, the machine learning method employed by the learning unit 24 is not limited, and any existing machine learning method may be used to perform machine learning.

The teaching data input to the learning unit 24 includes the same number of data sets relating to the second event as the number of data sets relating to the first event. The learning unit 24 can output an estimation model that is dominated by none of the first event and the second event.

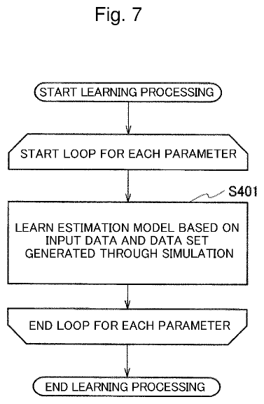

A learning processing that is executed by the learning unit 24 will be described with reference to FIG. 7.

The learning unit 24 repeats processing in step S401 for each parameter. In step S401, the learning unit 24 learns an estimation model based on the data sets of the input data 11 and the data set generated for each processing target parameter by the simulation unit 23.

When the processing in step S401 for the parameters is ended, the learning unit 24 ends the processing.

The verification unit 25 inputs the validation data 15 to the estimation model learned by the learning unit 24, compares the event indicated by the validation data 15 to the event obtained from the estimation model, and outputs the uncertainty of the estimation model. Using the estimation model deviated from the data obtained by correcting the imbalance of the input data 11, the verification unit 25 determines each of the data sets of the validation data 15 whose imbalance was not corrected, and checks and verifies the behavior thereof. The uncertainty of the estimation model output by the verification unit 25 relates to the data sets relating to the second event generated by the simulation unit 23.

The learning unit 24 generates a plurality of estimation models, namely, the estimation model generated for the parameter estimated by the copula function estimation unit 21, and the estimation model generated for the parameter generated by the parameter generation unit 22. If the parameter generation unit 22 generates a plurality of parameters, three of more estimation models may be generated by the learning unit 24.

The verification unit 25 inputs the validation data 15 to each of the plurality of estimation models thus generated, and evaluates whether or not the event indicated by each estimation model matches the event indicated in the validation data 15. For example, if a data set of the validation data 15 that relates to the first event is input to an estimation model, and the estimation model indicates the first event, this means that the estimation model outputs a correct answer. Also, if a data set of the validation data 15 that relates to the first event is input to an estimation model, and the estimation model indicates the second event, this means that the estimation model outputs a wrong answer. In this way, the verification unit 25 compares the event output by an estimation model with the event indicated by the validation data 15, and outputs the certainty of the estimation model.

The embodiment of the present invention describes a case in which the verification unit 25 verifies a plurality of estimation models, but the present invention is not limited to this. The verification unit 25 may verify only one estimation model for the parameter obtained from the minor data of the input data 11.

The index with which the verification unit 25 outputs the uncertainty is suitably set. Examples of the index may include an overall correct answer rate, a degradation correct answer rate, a missing answer rate, and a false answer rate. The overall correct answer rate refers to a correct answer rate that is obtained regardless of the first event (non-failure) and the second event (failure), and is a probability that the event output from the estimation model matches the event indicated by the data set of the validation data 15. The degradation correct answer rate refers to a correct answer rate regarding only the data sets of the validation data 15 that indicate the second event (failure). The missing answer rate refers to a probability in the number of data sets of the validation data 15 that relate to the second event but are estimated by the estimation model as relating to the first event of the validation data 15. The false answer rate refers to a probability in the number of data sets of the validation data 15 that relate to the first event but are estimated as relating to the second event of the validation data 15.

The verification unit 25 sets these necessary indices, performs calculation using a preset calculation method, and outputs the results.

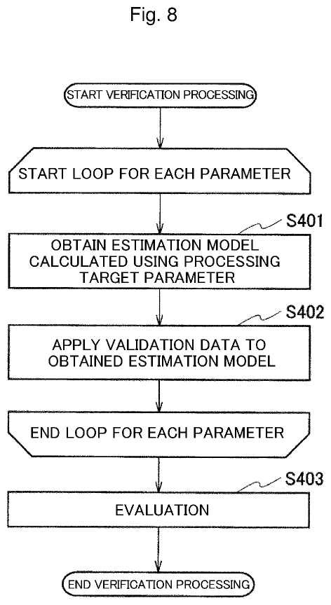

A verification processing that is executed by the verification unit 25 will be described with reference to FIG. 8.

First, the verification unit 25 performs, for each parameter, processing in steps S401 and S402. In step S401, the verification unit 25 obtains an estimation model calculated using a processing target parameter. Instep S402, the verification unit 25 applies the data sets of the validation data 15 to the estimation model obtained in step S401, so as to obtain an event estimated by the estimation model for each data set.

Upon completion of the processing in steps S401 and S402 for each parameter, the result of the application to the estimation model in step S402 is evaluated in step S403. The verification unit 25 may evaluate, for each parameter, the result of application to the estimation model, or may evaluate the results obtained for the parameters together.

The verification unit 25 outputs the evaluation obtained in step S403, and ends the processing.

### (Copula)

Hereinafter, a copula will be described. In the description of a copula, a “marginal distribution” refers to each of distributions that constitute a simultaneous distribution, and means a variable A and a variable B contained in a data set.

The basic theory of a copula is explicated based on the Sklar's theorem. Letting an arbitrary d-dimensional distribution function be F, there is a d-dimensional joint function C as given by Expression (1). The d-dimensional joint function C is referred to as “copula”.

Math. 1

C(u₁, . . . ,u_{d})=F(F₁⁻¹(u₁), . . . ,F_{d}⁻¹(u_{d})) Expression (1)

C: Copula

d: Order of variable

u_{d}: Variable

F₁: i-th one-dimensional marginal distribution function of F (i=1, . . . , d)

F⁻¹: Inverse function of F

If F is continuous, C is uniquely defined, and C is referred to as a joint function of F. In this case, C is given by Expression (2).

Math. 2

C(u₁, . . . ,u_{d})=F(F₁⁻¹(u₁), . . . ,F_{d}⁻¹(u_{d}) Expression (2)

A copula is given based on distribution functions, and thus couples uniform distributions. In other words, it can be said that a copula is a function in which information of the original marginal distribution is lost and only the correlation and relationship between distribution functions of the marginal distribution.

Kendall's τ is often used as an index that indicates the strength of the correlation and relationship between distribution functions of the marginal distribution that a copula has, that is, the strength of the mutual dependency. τ is a Kendall's rank correlation coefficient. τ takes a value from −1 to 1, and an increase in the value means that the mutual dependency is strong. τ indicates 1 if ranks completely match each other, τ indicates 0 if the ranks are completely independent from each other, and τ indicates −1 if the ranks do not completely match each other.

Some types of copula functions are provided, and there is a multi-dimensional copula such as a two-dimensional copula, or a three-, or more dimensional copula. Each copula function has a parameter, and the distribution varies depending on the parameters. The number of parameters varies depending on the type of copula function. Also, each copula function parameter and Kendall's τ are related to each other.

The copula function estimation unit 21 specifies, for the minor data of the input data 11, a copula function that indicates the relationship between the variable A and the variable B, out of a plurality of types of copula functions. The copula function estimation unit 21 further specifies the value of a parameter for use in the specified copula function.

### Working Example

A working example of the learning device 1 according to the embodiment of the present invention will be described.

The data sets included in the input data 11 and the validation data 15 are ten thousand data sets randomly extracted from observational data of neutron stars disclosed in NPLs 2 and 3. In the working example, the value 0 recorded in “class data” of the observational data of neutron stars is read as an identifier that indicates a non-failure event of equipment, and the value 1 is read as an identifier that indicates a failure event of equipment. Note that in the “class data” of the observational data, the number of data sets with the value 0 is larger than the number of data sets with the value 1.

In the observational data of NPLs 2 and 3, values of eight items are recorded, but in the working example, two of the eight items are respectively used as values of the variable A and the variable B. With this measure, a plurality of data sets are obtained for determining whether or not there is a failure based on the variable A and the variable B.

First, the plurality of data sets are classified into the input data 11 for generating an estimation model and the validation data 15 for verifying the estimation model. Any method may be used for the classification, as long as there is no deviation between a plurality of data set classified into the input data 11 and a plurality of data sets classified into the validation data 15. For example, there is a method for randomly classifying the data sets. Also, in the working example, the number of data sets classified into the input data 11 and the number of data sets classified into the validation data 15 have a 1 to 1 relationship, but may be different ratio.

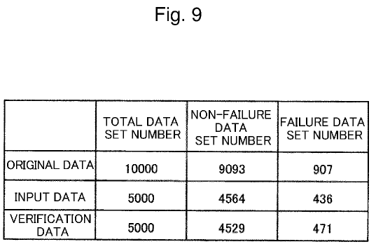

FIG. 9 shows content of the input data 11 and the validation data 15 into which the ten thousand data sets are classified in the working example. In both the input data 11 and the validation data 15, the ratio of the number of data sets indicating that there is no failure (data sets indicating non-failure) to the number of data sets indicating that there is a failure (data sets indicating a failure) is about 10:1, that is, the data sets are in an imbalanced state. In the working example, of the input data 11, the data including the data sets indicating non-failure is major data, and the data including the data sets indicating a failure is minor data.

In this way, when the input data 11 and the validation data 15 are determined, the copula function estimation unit 21 estimates a copula function and a parameter set. The copula function estimation unit 21 performs copula analysis with reference to the minor data of the input data 11, that is, the data sets indicating a failure. As the copula analysis, a typical method may be used. In the working example, the copula that indicates the mutual dependency between the variable A and the variable B, and the parameter set for this copula are estimated in the following manner. The parameter set in the working example includes a parameter θ and a parameter δ.

The copula function: BB8,

Copula parameter θ: 5.14,

parameter δ: 0.62,

Kendall's τ: 0.41,

The definition expression of the BB8 Copula is given by Expression (3) below.

$$C ( u , v ; θ , δ ) = {δ}^{- 1} ( 1 - {\{ 1 - {η}^{- 1} [ 1 - {( 1 - δ u )}^{θ} ] [ 1 - {( 1 - δ v )}^{θ} ] \}}^{\frac{1}{θ}} ) \\ θ \geq 1 , 0 < δ \leq 1 , where η = 1 - {( 1 - δ )}^{θ} and 0 \leq u , v \leq 1 \qquad Math . 3$$

### Expression (3)

When the copula function and the parameter set of the minor data have been estimated, the parameter generation unit 22 increases the number of parameter sets. In the working example, the parameter generation unit 22 generates, in addition to the parameter set (θ, δ)=(5.14, 0.64) estimated by the copula function estimation unit 21, 999 parameter sets, and prepares in total of 1000 parameter sets. The parameter generation unit 22 generates a plurality of parameter sets by randomly assigning the values of θ and δ. If the possible ranges of the parameters of the copula function are mathematically defined, the defined ranges are also applied to the ranges of the values of θ and δ. If the possible ranges of the parameters of the copula function are not defined, the ranges of the values of θ and δ may be suitably set by a user or may be set in advance in the system. In the working example, 1000 parameter sets of θ and δ are generated within a range of 1≤θ<8 and 0<δ≤1.

When the parameter sets have been generated, the simulation unit 23 performs simulation of a marginal distribution for each parameter set. The simulation unit 23 increases the number of data sets of the minor data in order to correct the imbalance of the input data 11. As shown in FIG. 9, in the input data 11, the major data contains 4564 data sets, and the minor data contains 436 data sets. Accordingly, the simulation unit 23 generates, through the simulation, 4128 data sets, which is the number obtained by subtracting 436 for the number of data sets of the minor data from 4564 for the number of data sets of the major data, for each parameter set.

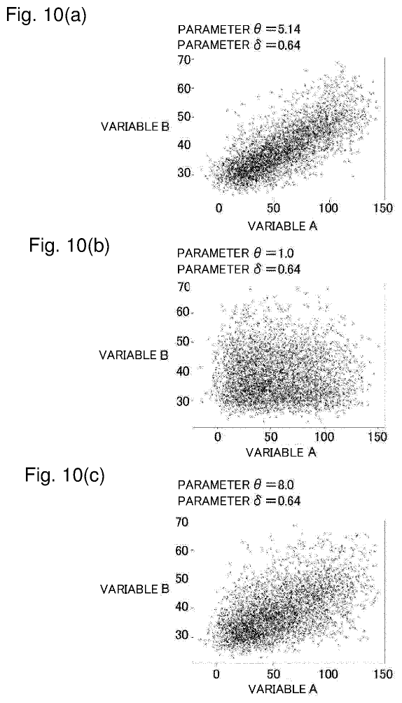

FIG. 10 show examples of data sets generated by the simulation unit 23. FIG. 10(a) shows a marginal distribution of the variable A and the variable B simulated for the parameter set (θ, δ)=(5.14, 0.64) estimated by the copula function estimation unit 21. FIG. 10(b) shows a marginal distribution of the variable A and the variable B simulated for the parameter set (θ, δ)=(1.0, 0.64) generated by the parameter generation unit 22. FIG. 10(c) shows a marginal distribution of the variable A and the variable B simulated for the parameter set (θ, δ)=(8.0, 0.64) generated by the parameter generation unit 22.

Note that the marginal distribution shown in FIG. 10(a) is formed in the shape of a band extending from the lower left to upper right, and the density tends to be higher in a lower left portion than in an upper right portion. Accordingly, the copula function estimation unit 21 estimates a copula function that can express such a relationship between the variables. Also, the distributions have different dispersion degrees depending on the parameter sets, but in both of the distributions of FIGS. 10(b) and 10(c), similar to FIG. 10(a), the marginal distributions are formed in the shape of a band extending from the lower left to the upper right, and the density tends to be higher in a lower left portion than in an upper right portion.

By the simulation unit 23, the number of data sets of the major data and the number of data sets of the minor data match each other for each parameter set, and the imbalance in the teaching data is resolved. The teaching data refers to data sets of the input data 11 and the data sets generated by the simulation unit 23.

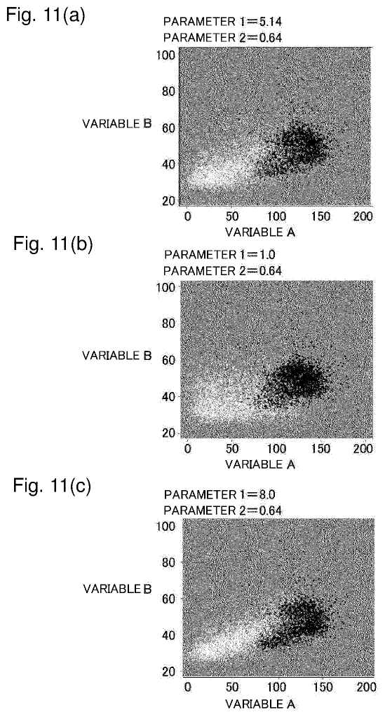

A distribution of the teaching data will be described with reference to FIG. 11. FIG. 11(a) shows a marginal distribution of the variable A and the variable B of the data sets of the input data 11, and the data sets simulated for the parameter set (θ, δ)=(5.14, 0.64) estimated by the copula function estimation unit 21. FIG. 11(b) shows a marginal distribution of the variable A and the variable B of the data sets of the input data 11, and the data sets simulated for the parameter set (θ, δ)=(1.0, 0.64) generated by the parameter generation unit 22. FIG. 11(c) shows a marginal distribution of the variable A and the variable B of the data sets of the input data 11, and the data sets simulated for the parameter set (θ, δ)=(8.0, 0.64) generated by the parameter generation unit 22.

In the respective drawings of FIG. 11, a black point indicates a data set indicating non-failure, and a white point indicates a data set indicating a failure. The data sets of the white points include, in addition to the data sets included in the input data 11, the data sets generated by the simulation unit 23. In the working example, a data set group as shown in each drawing of FIG. 11 is generated for each of 1000 parameter sets.

The learning unit 24 generates an estimation model for each parameter set from the teaching data whose imbalance has been resolved. In the working example, 1000 estimation models are generated. In the working example, the learning unit 24 derives, using a support vector machine, the estimation models capable of distinguishing the events from each other.

The verification unit 25 outputs an index regarding the uncertainty for each of the estimation models generated by the learning unit 24.

Typically, even if only an estimation result obtained by machine learning is provided, it is conceivable that it is not sufficient for actual maintenance of equipment or the like. In many cases, estimation behavior by machine learning is uncertain, and an estimation result can potentially cover a large scope. In other words, if maintenance planning is created using estimation, it is required to consider the uncertainty of the estimation.

The learning device 1 according to the embodiment of the present invention generates, for each parameter set, a data set of minor data, and generates estimation models for groups different for each parameter set. The parameter set is set in a range in which a copula function parameter is mathematically defined, or in a possible range that a copula function parameter can cover. Accordingly, the parameter sets respectively defines different populations to which the minor data can belong. Accordingly, the estimation model group generated by the learning device 1 is constituted by estimation models that correspond to the different populations to which the minor data can belong. The verification unit 25 outputs various types of indices for the estimation model group thus generated. By using these estimation model groups for verification, information on the uncertainty of machine learning results involved in resampling of the minor data can be obtained.

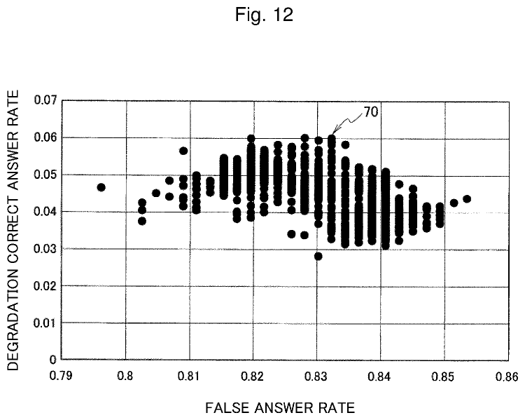

FIG. 12 shows an example of a verification result output by the verification unit 25. FIG. 12 shows a relationship between the degradation correct answer rate and the false answer rate when in the working example, the validation data 15 is applied to 1000 estimation models. A black mark 70 shown in FIG. 12 indicates a degradation correct answer rate and a false answer rate when the validation data 15 is applied to an estimation model corresponding to one parameter set.

It is apparent from the verification result shown in FIG. 12 that the degradation correct answer rate can cover the range from about 0.80 to 0.85, and the false answer rate can cover the range from about 0.03 to 0.06. The verification result shown in FIG. 12 can indicate, to a maintenance planner, that a maintenance plan should be made using the estimation models on the assumption that the estimation models according to the embodiment of the present invention may have a deviation to the extent shown in FIG. 12.

Note that the verification result indicated by the verification unit 25 may be indicated by a graph of the relationship between indices as shown in FIG. 12 or by an approximate function. Also, if index values or a range of the index values that are set as a target in maintenance is determined, the verification unit 25 may also indicate, of the plurality of estimation models generated by the learning unit 24, only the verification result relating to the estimation model that meet the target.

According to such a learning device 1 of the embodiment of the present invention, it is possible to increase the number of data sets reflecting the mutual dependency of variates of the minor data of the input data 11, through simulation of a copula function. Accordingly, even if there is imbalance in the input data 11, the learning device 1 can even out the numbers of the data sets indicating the respective events. Accordingly, the estimation models to be output by the learning device 1 can prevent the tendency of minimizing the wrong answer rate for the major data, and can minimize the wrong answer rate for the major data and the minor data.

Also, the learning device 1 generates a plurality of copula function parameter sets, and generates an estimation model for each parameter set. Accordingly, the learning device 1 can generate a plurality of estimation models that has the tendency obtained from the input data 11.

Furthermore, the learning device 1 verifies the estimation model generated for each parameter set. With this, the learning device 1 can recognize in advance the promising range of the result or the degree of possible deviation of estimation, and thus can digitalize the uncertainty of each estimation model. Also, because an accurate range of the estimation model output by the learning device 1 can be obtained, the estimation accuracy using this estimation model is improved, and maintenance planning is possible that takes into consideration the uncertainty that occurs by resampling of imbalanced data.

### OTHER EMBODIMENTS

As described above, the embodiment and the working example of the present invention have been described, but the description and the drawings that constitute a portion of this disclosure are not to be construed as limiting the invention. Various alternative embodiments, working examples, and operational techniques will be apparent to a person skilled in the art from this disclosure.

For example, the learning device described in the embodiment of the present invention may be configured on one piece of hardware as shown in FIG. 1, or may be configured on a plurality of pieces of hardware that correspond to the number of functions and processes thereof. Also, the learning device may be realized on an existing information processing device that realizes another function.

The present invention of course includes various embodiments and the like that have not been described here. Accordingly, the technical scope of the present invention is defined only by invention specifying matters according to the claims appropriate from the above description.

### REFERENCE SIGNS LIST

1 Learning device
10 Storage device
11 Input data
12 Parameter data
13 Simulation data
14 Estimation model data
15 Validation data
20 Processing device
21 Copula function estimation unit
22 Parameter generation unit
23 Simulation unit
24 Learning unit
25 Verification unit
30 Input/output interface

1. A learning device for performing machine learning with reference to a plurality of data sets, comprising:
a storage device configured to store input data that contains a plurality of data sets relating to a first event, and a plurality of data sets relating to a second event, the number of the data sets relating to the second event being smaller than the number of the data sets relating to the first event;
a copula function estimation unit configured to estimate a copula function and a parameter for use in the copula function, based on the data sets relating to the second event;
a simulation unit configured to generate a data set relating to the second event through simulation using the copula function and the parameter; and
a learning unit configured to learn an estimation model for distinguishing the first event and the second event from each other, with reference to the input data, and the data set relating to the second event generated by the simulation unit.

2. The learning device according to claim 1, further comprising, a parameter generation unit configured to generate a new parameter other than the parameter estimated by the copula function estimation unit, wherein the simulation unit generates a data set relating to the second event for the new parameter through simulation using the copula function and the new parameter, and the learning unit learns an estimation model for the new parameter, with reference to the input data, and the data set relating to the second event generated for the new parameter by the simulation unit.

3. The learning device according to claim 1, further comprising, a verification unit configured to input validation data that contains a plurality of data sets relating to the first event and a plurality of data sets relating to the second event to the estimation model learned by the learning unit, compare an event indicated by the validation data with an event obtained from the estimation model, and output the uncertainty of the estimation model.

4. A learning method for performing machine learning with reference to a plurality of data sets, comprising:
a step of a computer storing, in a storage device, input data that contains a plurality of data sets relating to a first event, and a plurality of data sets relating to a second event, the number of the data sets relating to the second event being smaller than the number of the data sets relating to the first event;
a step of the computer estimating a copula function and a parameter for use in the copula function, based on the data sets relating to the second event;
a step of the computer generating a data set relating to the second event through simulation using the copula function and the parameter; and
a step of the computer learning an estimation model for distinguishing the first event and the second event from each other, with reference to the input data and the generated data set relating to the second event.

5. The learning method according to claim 4, further comprising:
a step of the computer generating a new parameter other than the parameter estimated in the step of estimating;
a step of the computer generating a data set relating to the second event for the new parameter through simulation using the copula function and the new parameter; and
a step of the computer learning an estimation model for the new parameter, with reference to the input data, and the data set relating to the second event generated for the new parameter.

6. The learning method according to claim 4, further comprising: a step of the computer inputting validation data that contains a plurality of data sets relating to the first event and a plurality of data sets relating to the second event to the estimation model, comparing an event indicated by the validation data with an event obtained from the estimation model, and outputting the uncertainty of the estimation model.

7. A learning program for causing a computer to function as the learning device according to claim 1.

8. The learning device according to claim 2, further comprising, a verification unit configured to input validation data that contains a plurality of data sets relating to the first event and a plurality of data sets relating to the second event to the estimation model learned by the learning unit, compare an event indicated by the validation data with an event obtained from the estimation model, and output the uncertainty of the estimation model.

9. The learning method according to claim 5, further comprising: a step of the computer inputting validation data that contains a plurality of data sets relating to the first event and a plurality of data sets relating to the second event to the estimation model, comparing an event indicated by the validation data with an event obtained from the estimation model, and outputting the uncertainty of the estimation model.

10. A learning program for causing a computer to function as the learning device according to claim 2.

11. A learning program for causing a computer to function as the learning device according to claim 3.
